(19) United States
(12) Patent Application Publication
(10) Pub. No.: US 2025/0169327 A1
(43) Pub. Date: May 22, 2025

(54) DISPLAY MODULE AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Kejin Song, Beijing (CN); Jing Wang, Beijing (CN); Jie Zeng, Beijing (CN); Zhilong Chen, Beijing (CN); Wenfeng Guo, Beijing (CN); Chengyi Li, Beijing (CN); Guoyan Liu, Beijing (CN); Xiaoyu Tang, Beijing (CN); Guangjie Yang, Beijing (CN); Hongdou Zhao, Beijing (CN)

(21) Appl. No.: 18/841,388

(22) PCT Filed: Nov. 13, 2023
(86) PCT No.: PCT/CN2023/131273

§ 371 Date: Aug. 25, 2024

(30) Foreign Application Priority Data
Dec. 7, 2022 (CN) 202211569362.3

(51) Int. Cl. H10K 59/80; H01Q 1/22; H01Q 1/52; H05K 1/02; H10K 59/95; H10K 102/00

(52) U.S. Cl. CPC H10K 59/80; H01Q 1/22; H01Q 1/526; H05K 1/0268; H10K 59/95; H05K 1/0277; H05K 2201/10098; H10K 2102/311

(57) ABSTRACT

A display module and a display device are provided. The display module includes a display substrate, including a display portion, a bending portion and a binding portion, the binding portion is bent to a back side of the display portion through the bending portion; a display driving chip, being bound to the binding portion; a near field communication antenna, located on the back side of the display portion, an orthographic projection of the near field communication antenna on the display portion is spaced apart from an orthographic projection of the display driving chip on the display portion; and a first shielding layer, the first shielding layer is located on a side of the display driving chip away from the display portion, and the orthographic projection of the display driving chip on the display portion is located within an orthographic projection of the first shielding layer on the display portion.

### CROSS REFERENCE TO RELATED APPLICATION

This application claims priority to Chinese Application No. 202211569362.3 filed on Dec. 7, 2022, the entire content of which is incorporated herein by reference in its entirety.

### TECHNICAL FIELD

The present disclosure relates to a field of display technology, and in particular, to a display module and a display device.

### BACKGROUND

With the development of science and technology, more and more smart wearable products (such as smart wristbands, rings, etc.) have entered people's lives. Taking smart watches as an example, users may use smart watches to record real-time data such as exercise, sleep and diet in daily life, and synchronize these data with terminal devices such as mobile phones and tablets, so as to achieve the purpose of guiding healthy life through data.

Near Field Communication (NFC) is a contactless identification and interconnection technology, which adopts near field magnetic field communication, and has the characteristics of short transmission distance, low energy consumption, and signal is not easily interfered. The NFC may perform short-range wireless communication between mobile devices and consumer electronic products.

At present, near field communication technology has been widely used in smart wearable products, but smart wearable products integrated with communication technology will have water ripples during wireless charging.

### SUMMARY

In view of the above problems, the present disclosure provides a display module and a display device.

A first aspect of the present disclosure provides a display module, including:

a display substrate, wherein the display substrate comprises a display portion, a bending portion and a binding portion, and the binding portion is bent to a back side of the display portion through the bending portion;

a display driving chip, wherein the display driving chip is bound to the binding portion;

a near field communication antenna, wherein the near field communication antenna is located on the back side of the display portion, and an orthographic projection of the near field communication antenna on the display portion is spaced apart from an orthographic projection of the display driving chip on the display portion; and

a first shielding layer, wherein the first shielding layer is located on a side of the display driving chip away from the display portion, and the orthographic projection of the display driving chip on the display portion is located within an orthographic projection of the first shielding layer on the display portion.

According to the embodiments of the present disclosure, the display module further includes a second shielding layer, the second shielding layer is located on a side of the display driving chip close to the display portion, and the orthographic projection of the display driving chip on the display portion is located within an orthographic projection of the second shielding layer on the display portion.

According to the embodiments of the present disclosure, the orthographic projection of the near field communication antenna on the display portion is spaced apart from the orthographic projection of the second shielding layer on the display portion.

According to the embodiments of the present disclosure, the orthographic projection of the second shielding layer on the display portion is located within the orthographic projection of the first shielding layer on the display portion.

According to the embodiments of the present disclosure, the orthographic projection of the near field communication antenna on the display portion is spaced apart from the orthographic projection of the first shielding layer on the display portion.

According to the embodiments of the present disclosure, the display driving chip is located on a side of the binding portion away from the display portion, and the second shielding layer is located on a side of the binding portion facing the display portion.

According to the embodiments of the present disclosure, the display module further includes:
a flexible circuit board electrically connected to the binding portion and the near field communication antenna, and the flexible circuit board is located on a side of the near field communication antenna away from the display portion; and
a third shielding layer located between the near field communication antenna and the flexible circuit board.

According to the embodiments of the present disclosure, an orthographic projection of the third shielding layer on the display portion is spaced apart from the orthographic projection of the first shielding layer on the display portion.

According to the embodiments of the present disclosure, the first shielding layer is located on a side of the flexible circuit board away from the display portion, and an orthographic projection of a part of the flexible circuit board electrically connected to the binding portion on the display portion is located within the orthographic projection of the first shielding layer on the display portion.

According to the embodiments of the present disclosure, the flexible circuit board includes a base layer and a wiring layer, the wiring layer is located on a side of the base layer away from the display portion, and a side of the base layer close to the display portion is bound and connected to a side of the binding portion away from the display portion.

According to the embodiments of the present disclosure, the binding portion includes a first portion, a second portion and a third portion arranged in sequence along a first direction, the first portion is bound and connected to the base layer, the second portion is bound and connected to the display driving chip, and the third portion is electrically connected to the bending portion.

According to the embodiments of the present disclosure, at least one opening is provided on the near field communication antenna, the at least one opening is configured to provide a photosensitive element, an orthographic projection of the opening on the display portion and an orthographic projection of the flexible circuit board on the display portion are arranged along a second direction, and the second direction intersects with the first direction.

According to the embodiments of the present disclosure, at least one signal test terminal is provided on the flexible circuit board, and an orthographic projection of the signal test terminal on the display portion is spaced apart from the orthographic projection of the first shielding layer on the display portion.

According to the embodiments of the present disclosure, the display module further includes a second shielding layer, the second shielding layer is located on a side of the display driving chip close to the display portion, the orthographic projection of the display driving chip on the display portion is located within an orthographic projection of the second shielding layer on the display portion; and

an orthographic projection of the flexible circuit board on the display portion is spaced apart from the orthographic projection of the second shielding layer on the display portion.

According to the embodiments of the present disclosure, the near field communication antenna is bound and connected to the flexible circuit board.

According to the embodiments of the present disclosure, the display module further includes a covering tape, the covering tape is located on a side of the first shielding layer away from the display portion, and the orthographic projection of the first shielding layer on the display portion is located within an orthographic projection of the covering tape on the display portion.

According to the embodiments of the present disclosure, an orthographic projection of the binding portion on the display portion is located within the orthographic projection of the first shielding layer on the display portion.

According to the embodiments of the present disclosure, a material of the first shielding layer comprises a ductile metal material.

A second aspect of the present disclosure provides a display module, including:
a display substrate, wherein the display substrate comprises a display portion, a bending portion and a binding portion, and the binding portion is bent to a back side of the display portion through the bending portion;
a display driving chip, wherein the display driving chip is bound to the binding portion;
a near field communication antenna, wherein the near field communication antenna is located on the back side of the display portion, and an orthographic projection of the near field communication antenna on the display portion is spaced apart from an orthographic projection of the display driving chip on the display portion;
a first shielding layer, wherein the first shielding layer is located on a side of the display driving chip away from the display portion, and the orthographic projection of the display driving chip on the display portion is located within an orthographic projection of the first shielding layer on the display portion; and
a support structure located on a side of the display driving chip close to the display portion, wherein the support structure comprises a second shielding layer, and an orthographic projection of the display driving chip on the display portion is located within an orthographic projection of the second shielding layer on the display portion.

According to the embodiments of the present disclosure, the support structure is located between the binding portion and the display portion, and the support structure is configured to support the binding portion and the display portion.

According to the embodiments of the present disclosure, the support structure further comprises a spacer layer and a first adhesive layer, the spacer layer is located on a side of the second shielding layer close to the display portion, and the first adhesive layer is located between the spacer layer and the second shielding layer.

According to the embodiments of the present disclosure, the orthographic projection of the near field communication antenna on the display portion is spaced apart from the orthographic projection of the second shielding layer on the display portion.

According to the embodiments of the present disclosure, the orthographic projection of the second shielding layer on the display portion is located within the orthographic projection of the first shielding layer on the display portion.

According to the embodiments of the present disclosure, the orthographic projection of the near field communication antenna on the display portion is spaced apart from the orthographic projection of the first shielding layer on the display portion.

According to the embodiments of the present disclosure, the display module further includes:
a flexible circuit board electrically connected to the binding portion and the near field communication antenna, and the flexible circuit board is located on a side of the near field communication antenna away from the display portion; and
a third shielding layer located between the near field communication antenna and the flexible circuit board.

According to the embodiments of the present disclosure, an orthographic projection of the third shielding layer on the display portion is spaced apart from the orthographic projection of the first shielding layer on the display portion.

According to the embodiments of the present disclosure, the first shielding layer is located on a side of the flexible circuit board away from the display portion, and an orthographic projection of a part of the flexible circuit board electrically connected to the binding portion on the display portion is located within the orthographic projection of the first shielding layer on the display portion.

According to the embodiments of the present disclosure, an orthographic projection of the flexible circuit board on the display portion is spaced apart from the orthographic projection of the second shielding layer on the display portion.

According to the embodiments of the present disclosure, the display module further includes a covering tape, the covering tape is located on a side of the first shielding layer away from the display portion, and the orthographic projection of the first shielding layer on the display portion is located within an orthographic projection of the covering tape on the display portion.

According to the embodiments of the present disclosure, an orthographic projection of the binding portion on the display portion is located within the orthographic projection of the first shielding layer on the display portion.

A third aspect of the present disclosure provides a display device, including the above mentioned display module.

### BRIEF DESCRIPTION OF THE DRAWINGS

The above contents and other purposes, features and advantages of the present disclosure will become clearer through the following description of embodiments of the present disclosure with reference to the accompanying drawings, in which:

FIG. 1 schematically shows a schematic diagram of a film layer stack on a back side of a display substrate in a comparative example;

FIG. 2 schematically shows a schematic diagram of a display substrate before bending in the embodiments of the present disclosure;

FIG. 3 schematically shows a plan view of components on a back side of a display portion in the embodiments of the present disclosure;

FIG. 4 schematically shows a cross-sectional view along a section line BB′ of FIG. 3;

FIG. 5 schematically shows a plan view of a display driving chip, a first shielding layer, a second shielding layer and a near field communication antenna in the embodiments of the present disclosure;

FIG. 6 schematically shows a cross-sectional view along a section line CC′ of FIG. 5;

FIG. 7 schematically shows a schematic diagram of a display module in another comparative example;

FIG. 8 schematically shows a first plan view of a display driving chip, a first shielding layer, a second shielding layer, a flexible circuit board and a near field communication antenna in the embodiments of the present disclosure;

FIG. 9 schematically shows a cross-sectional view of FIG. 8 along a section line DD′;

FIG. 10 schematically shows a cross-sectional view of a flexible circuit board, a near field communication antenna and a binding portion in the embodiments of the present disclosure;

FIG. 11 schematically shows a second plan view of a display driving chip, a first shielding layer, a second shielding layer, a flexible circuit board and a near field communication antenna in the embodiments of the present disclosure;

FIG. 12 schematically shows a plan view of a near field communication antenna in the embodiments of the present disclosure;

FIG. 13 schematically shows a plan view of a display driving chip, a covering tape, a first shielding layer, a second shielding layer, a flexible circuit board and a near field communication antenna in the embodiments of the present disclosure;

FIG. 14 schematically shows a cross-sectional view of FIG. 13 along a section line EE′.

### DETAILED DESCRIPTION OF EMBODIMENTS

In order to make the purpose, technical solutions and advantages of the embodiments of the present disclosure apparant, the technical solutions in the embodiments of the present disclosure will be clearly and completely described in conjunction with the drawings in the embodiments of the present disclosure. The affirmatively described embodiments constitute only a subset of the embodiments contemplated in view of the present disclosure, and not all of such embodiments. Based on the described embodiments of the present disclosure, further embodiments obtained by those skilled in the art without creative work are within the protection scope of the present disclosure.

It should be noted that, in the drawings, for clarity and/or description purposes, a size and relative size of an element may be enlarged, the size and relative size of each element need not be limited to those shown in the drawings. In the specification and drawings, the same or similar reference numerals indicate the same or similar components.

When an element is described as being “on”, “connected to” or “coupled to” another element, the element may be directly on the another element, directly connected to the another element or directly coupled to the another element, or an intermediate element may be present. However, when an element is described as being “directly on”, “directly connected to” or “directly coupled to” another element, there is no intermediate element. Other terms and/or expressions used to describe the relationship between elements should be interpreted in a similar manner, for example, “between” and “directly between”, “adjacent” and “directly adjacent”, “on” and “directly on” etc. In addition, the term “connect” may refer to a physical connection, an electrical connection, a communication connection, and/or a fluid connection. In addition, X axis, Y axis, and Z axis are not limited to the three axes of the Cartesian coordinate system, which may be interpreted in broader meaning. For example, the X axis, the Y axis, and the Z axis may be perpendicular to each other, or may represent different directions that are not perpendicular to each other. For the purpose of the present disclosure, “at least one of X, Y, and Z” and “at least one selected from a group consisting of X, Y, and Z” may be interpreted as only X, only Y, only Z, or any combination of two or more of X, Y, and Z such as XYZ, XY, YZ, and ZZ. As shown in the present disclosure, the term “and/or” includes any and all combinations of one or more of the related items.

It should be noted that although the terms “first”, “second”, etc. may be used to describe various components, members, elements, regions, layers and/or portions, these components, components, elements, regions, layers and/or portions should not be limited by these terms. Actually, the terms are used to distinguish one component, member, element, region, layer, and/or portion from another one. Thus, for example, a first component, a first member, a first element, a first region, a first layer, and/or a first portion described below may be referred to as a second component, a second member, a second element, a second region, a second layer and/or a second portion, which does not depart from the teachings of this disclosure.

For the convenience of description, the spatial relationship terms, for example, “upper”, “lower”, “left”, “right”, etc. may be used to describe the relationship between one element or feature and another element or feature as shown in figures. It should be understood that, in addition to an orientation described in figures, the spatial relationship terms include other different orientations of a device in operation. For example, if the device in figures is turned upside down, elements described as “below” or “lower” other elements or features will be oriented “on” or “upper” other elements or features.

In the present disclosure, the terms “substantially”, “approximately”, “circa”, “about” and other similar terms are used as approximate terms rather than as terms of degree, and these terms explain a inherent deviation of a measured value or a calculated value recognized by those skilled in the art. Taking into factors such as process fluctuations, measurement problems, and errors related to the measurement of specific quantities (i.e. the limitations of the measurement system), the “substantially” or “approximately” includes a stated value and means that a specific value determined by those skilled in the art is within an acceptable deviation range. For example, “approximately” may mean within one or more standard deviations, or within ±30%, ±20%, ±10%, ±5% of the stated value.

It should be noted that, in the present disclosure, the expression “same layer” refers to a film layer formed by the same film forming process, where the film layer is used to form a specific pattern, and then the same mask is used to pattern the film layer and form a layer structure through one patterning process. Depending on the specific pattern, the one patterning process may include multiple exposure, development or etching processes, and the specific pattern in the formed layer structure may be continuous or discontinuous. That is, a plurality of elements, components, structures and/or portions located in the “same layer” are made of the same material and formed by the same patterning process. Generally, the plurality of elements, components, structures and/or portions located in the “same layer” have approximately the same thickness.

Those skilled in the art should understand that, in the present disclosure, unless otherwise specified, the expression “height” or “thickness” refers to a size along a surface of each film layer arranged perpendicular to a display substrate, that is, the size in a light-emission direction of the display substrate, or the size in a normal direction of the display device.

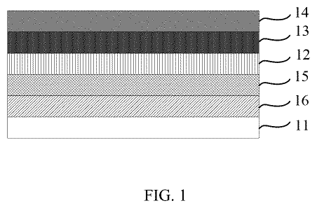

FIG. 1 schematically shows a schematic diagram of a film layer stack on a back side of a display substrate in a comparative example. Referring to FIG. 1, in the comparative example, a near field communication antenna 12, a flexible circuit board 13 and a display driving chip 14 are sequentially arranged in a direction away from a display substrate 11. Optionally, intermediate film layers such as an adhesive layer 15 and a foam layer 16 are arranged between the near field communication antenna 12 and the display substrate 11.

It should be noted that FIG. 1 only schematically shows a positional relationship between the near field communication antenna 12, the flexible circuit board 13 and the display driving chip 14 in a thickness direction of the display substrate 11, which does not constitute a limitation on the positional relationship between the near field communication antenna 12, the flexible circuit board 13 and the display driving chip 14 in a horizontal direction. For example, an orthographic projection of the display driving chip 14 on the display substrate 11 may be spaced apart from an orthographic projection of the flexible circuit board 13 on the display substrate 11.

It should also be noted that in the comparative example, the display substrate 11 may have a display portion, a bending portion and a binding portion. The binding portion may refer to a part of the display substrate 11 that is bound to the display driving chip 14 and other devices. The display portion may refer to a part of the display substrate 11 on which a display device is provided. The binding portion may be bent to a back side of the display portion through the bending portion, which is conducive to achieving a narrow frame. For the sake of clarity, only the display portion is shown in FIG. 1, and the display substrate 11 mentioned in the comparative example may specifically refer to the display portion of the display substrate 11.

It should also be noted that in the comparative example, the display portion includes not only a display area on the display substrate 11 that may display, but also a peripheral area that at least partially surrounds the display area. For example, a signal line lead may be provided in the peripheral area. The signal line lead may be bent to the binding portion through the bending portion, and bound and connected to the display driving chip 14 through structures such as pads on the binding portion.

In order to ensure that the near field communication antenna 12 may normally send and receive electromagnetic signals, in the comparative example, an original copper foil layer and other structures in an intermediate film layer are removed. However, this will cause the display driving chip 14 and the surrounding signal lines to lack shielding for electromagnetic signals, and the electromagnetic signals will interfere with the electrical signals output by the display driving chip 14, thereby causing the display screen to become abnormal, specifically manifested as poor water ripples.

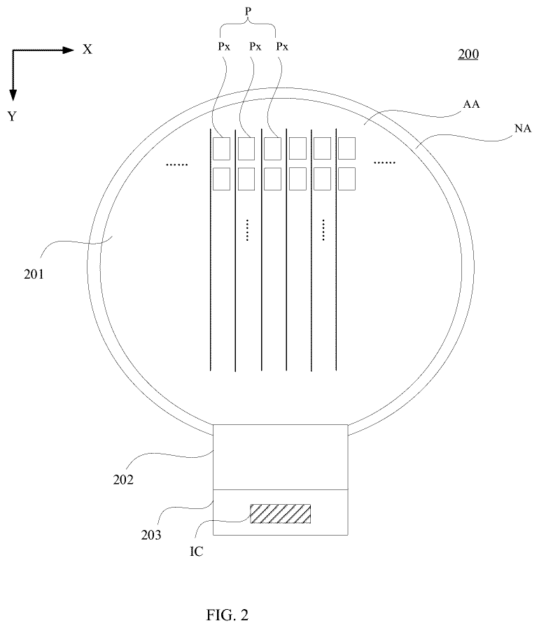

In view of this, the embodiments of the present disclosure provide a display module, which includes a display substrate 200. FIG. 2 schematically shows a schematic diagram of a display substrate before bending in the embodiments of the present disclosure. Referring to FIG. 2, the display substrate 200 includes a display portion 201, a bending portion 202 and a binding portion 203, and the display portion 201, the bending portion 202 and the binding portion 203 are arranged in sequence along a first direction Y. The binding portion 203 may be bound to elements such as a display driving chip 14. After the display substrate 200 is bent, the binding portion 203 may be bent to a back side of the display portion 201 through the bending portion 202.

Referring to FIG. 2, the display portion 201 includes a display area AA and a peripheral area NA at least partially surrounding the display area AA.

The display portion 201 may also include a gate driving circuit (not shown in the figure) and a display driving chip IC located in the peripheral area NA. For example, the gate driving circuit may be located on at least one side of the display area AA. In the embodiment shown in FIG. 2, the gate driving circuit may be located on left and right sides of the display area AA, respectively. It should be noted that the left and right sides may be left and right sides of the display substrate 200 (screen) viewed by the human eye during display. For example, the display driving chip IC may be located on at least one side of the display area AA. In the embodiment shown in FIG. 2, the display driving chip IC is located on a lower side of the display area AA. It should be noted that the lower side may be a lower side of the display substrate 200 (screen) viewed by the human eye during display.

The gate driving circuit may be implemented by a shift register, and the gate driving circuit may provide a scan signal to each gate line (not shown in the figure) on the display substrate 200.

It should be noted that although FIG. 2 shows that the gate driving circuit is located on the left and right sides of the display area AA, and the display driving chip IC is located on the lower side of the display area AA, the embodiments of the present disclosure are not limited thereto, and the gate driving circuit and the display driving chip IC may be located at any suitable position in the peripheral area NA.

For example, the gate driving circuit may adopt GOA technology, namely Gate Driver on Array. In GOA technology, the gate driving circuit is directly set on the display substrate 200 to replace the external chip. Each GOA unit serves as a shift register, and each shift register is connected to a gate line. The scanning signal is output in turn through each shift register to implement the row-by-row scanning of the pixel unit. In some embodiments, each shift register may also be connected to a plurality of gate lines. In this way, it may adapt to the development trend of high resolution and narrow frame of display substrate.

The display portion 201 may further include a plurality of pixel units P in the display area AA. The plurality of pixel units P are arranged in an array along a first direction Y and a second direction X, and the first direction Y intersects the second direction X. For example, the first direction Y is the vertical direction in FIG. 2, and the second direction X is the horizontal direction in FIG. 2, that is, the first direction Y and the second direction X are perpendicular to each other.

At least one pixel unit P includes a plurality of sub-pixels Px of different colors. For example, the plurality of sub-pixels Px in a pixel unit P may include a red sub-pixel, a green sub-pixel, and a blue sub-pixel.

It should be noted that FIG. 2 exemplarily shows that the shape of the orthographic projection of the sub-pixel on the substrate is a rectangle, but the embodiments of the present disclosure are not limited to this. Moreover, the arrangement of the three sub-pixels in a pixel unit P is not limited to the method shown in FIG. 2.

The display substrate 200 may further include a plurality of data lines DL arranged on the substrate 100 and located in the display area AA. As shown in FIG. 2, at least one of the plurality of data lines DL may extend from the upper end of the display area AA to the lower end of the display area AA, thereby being electrically connected to the display driving chip IC located at the lower end of the display area AA.

In the embodiments of the present disclosure, the plurality of data lines DL are arranged along a first direction Y, and at least one data line DL is electrically connected to the plurality of sub-pixels Px arranged along the first direction Y.

As shown in FIG. 2, the plurality of sub-pixels Px on a display substrate 200 may be arranged in an array along a first direction Y and a second direction X, and at least part of each column of sub-pixels Px may be electrically connected to the same data line DL. For example, for a column of sub-pixels Px, all sub-pixels Px in the column of sub-pixels Px are electrically connected to the same data line DL; or, odd-numbered rows of sub-pixels Px in the column of sub-pixels Px are electrically connected to the same data line, and even-numbered rows of sub-pixels Px are electrically connected to another data line DL.

The plurality of gate lines are arranged along a first direction Y, and at least one gate line is electrically connected to a plurality of sub-pixels Px arranged along the first direction Y.

As shown in FIG. 2, at least part of each row of sub-pixels Px may be electrically connected to the same gate line. For example, for a row of sub-pixels Px, all sub-pixels Px in the row of sub-pixels Px are electrically connected to the same gate line; or, odd-numbered column sub-pixels Px in the row of sub-pixels Px are electrically connected to the same data line, and even-numbered column sub-pixels Px are electrically connected to another data line DL.

In the embodiments of the present disclosure, the display substrate 200 may be a display substrate 200 applied to a liquid crystal display panel, or the display substrate 200 may also be a display substrate 200 applied to an organic electroluminescent display panel, and the embodiment of the present disclosure does not limit this.

For example, when the display substrate 200 is a display substrate 200 applied to an organic electroluminescent display panel, the sub-pixel may include an organic electroluminescent device and a pixel driving circuit for driving the light-emitting device to emit light.

Exemplarily, the light-emitting device may include stacked anode, organic light-emitting layer, and cathode. The pixel circuit may include a plurality of thin film transistors. For example, the pixel circuit may include a switch transistor, a drive transistor, a threshold compensation transistor, an initialization transistor, and a light-emitting control transistor, etc.

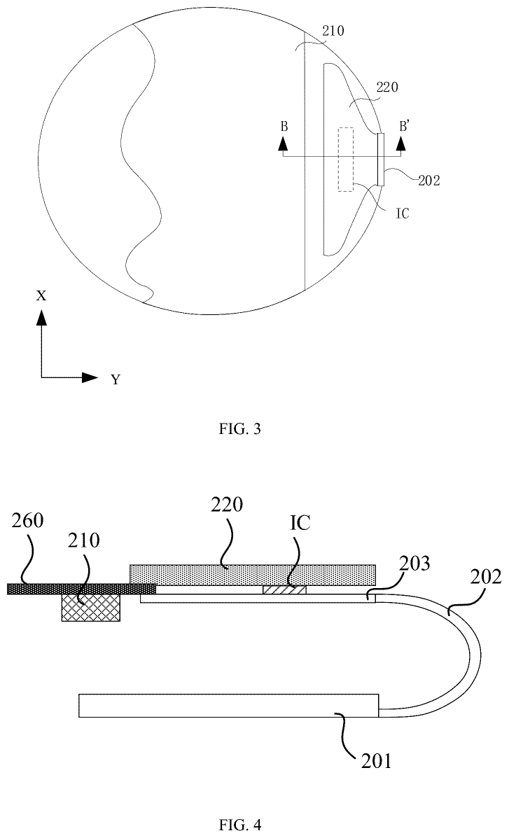

FIG. 3 schematically shows a plan view of components on a back side of a display portion in the embodiments of the present disclosure, and FIG. 4 schematically shows a cross-sectional view along a section line BB′ of FIG. 3. It should be noted that in FIG. 4, only the schematic diagram of the stacking of the film layers on the back side of the display portion 201 in the thickness direction of the display portion 201 is schematically shown, and this does not constitute a limitation on the position of the film layers in the horizontal direction in the embodiments of the present disclosure. It should also be noted that in FIG. 4, only the film layers more related to a first shielding layer are schematically shown, and other film layers are hidden. For example, a middle film layer between the near field communication antenna and the foam layer is hidden, and this does not constitute a limitation on the film layers of the display module in the embodiments of the present disclosure. The cross-sectional views involved below are all like this, so they will not be repeated below.

Referring to FIG. 3 and FIG. 4, the binding portion 203 is bent to the back side of the display portion 201 through the bending portion 202. In addition to the above-mentioned display substrate 200, the display module further includes a display driving chip IC, a near field communication antenna 210 and a first shielding layer 220. The display driving chip IC is bound to the binding portion 203 of the display substrate 200.

It should be noted that FIG. 3 shows that the display driving chip IC is located on a side of the binding portion 203 away from the display portion 201, but this does not constitute a limitation on the binding position of the display driving chip IC and the binding portion 203. For example, the display driving chip IC may also be located on a side of the binding portion 203 close to the display portion 201.

In the embodiments of the present disclosure, the display driving chip IC may include a source driving circuit, which may provide an electrical signal for driving the sub-pixel to emit light to each signal line on the display substrate 200. For example, the source driving circuit may provide a data signal to the data signal line DL, provide a constant high-level voltage signal to the power line, provide an initialization signal to the initialization signal line, and so on.

The near field communication antenna 210 is located on the back side of the display portion 201. For example, the near field communication antenna 210 may be first bound to the flexible circuit board 13, and then the near field communication antenna 210 and the flexible circuit board 13 may be arranged on the back side of the display portion 201. The near field communication antenna 210 may emit an electromagnetic signal in response to an electrical signal, or generate an electrical signal in response to an electromagnetic signal, thereby implementing functions such as data exchange and charging.

Exemplarily, the near field communication antenna 210 may transmit or receive electromagnetic signals through an antenna pattern, and the antenna pattern may be located on at least one surface of the near field communication antenna 210. Optionally, the antenna pattern may be located on two surfaces of the near field communication antenna 210 that are arranged opposite to each other, thereby implementing the transmission and reception of electromagnetic signals in two directions. For example, the antenna pattern may be located on a surface of the near field communication antenna 210 close to the display portion 201 and a surface of the near field communication antenna 210 away from the display portion 201.

Exemplarily, the display module in the embodiments of the present disclosure may be applied to smart wearable products. Taking a smart watch as an example, when data exchange is implemented through the near field communication antenna 210, the display surface of the smart watch may be close to the corresponding data interaction terminal to implement data interaction. When charging is implemented through the near field communication antenna 210, the back of the smart watch may be close to the charging terminal to implement the charging function.

Referring to FIG. 3 and FIG. 4, an orthographic projection of the near field communication antenna 210 on the display portion 201 is spaced from an orthographic projection of the display driving chip IC on the display portion 201, so that the main path of electromagnetic signal propagation may avoid the display driving chip IC.

Exemplarily, the orthographic projection of the near field communication antenna 210 on the display portion 201 may at least partially surround the orthographic projection of the display driving chip IC on the display portion 201, or the orthographic projection of the near field communication antenna 210 on the display portion 201 and the orthographic projection of the display driving chip IC on the display portion 201 may be arranged along the first direction Y. For example, referring to FIG. 3, the orthographic projection of the near field communication antenna 210 on the display portion 201 is located to the left of the orthographic projection of the display driving chip IC on the display portion 201.

Referring to FIG. 3 and FIG. 4, the first shielding layer 220 is located on a side of the display driving chip IC away from the display portion 201, and the orthographic projection of the display driving chip IC on the display portion 201 is located within the orthographic projection of the first shielding layer 220 on the display portion 201. In this way, when charging, for the electromagnetic signal between the near field communication antenna 210 and the charging terminal, a part passing through the display driving chip IC will be shielded by the first shielding layer 220, thereby preventing the electromagnetic signal from interfering with the electrical signal output by the display driving chip IC, and thereby improving the caused water ripple defect.

The display module of the embodiments of the present disclosure is further described below in conjunction with FIGS. 2 to 14.

The inventor found in the study that in the example shown in FIG. 1, after the original copper foil layer and other structures in the intermediate film layer are removed, the anti-static ability of the display module also decreases.

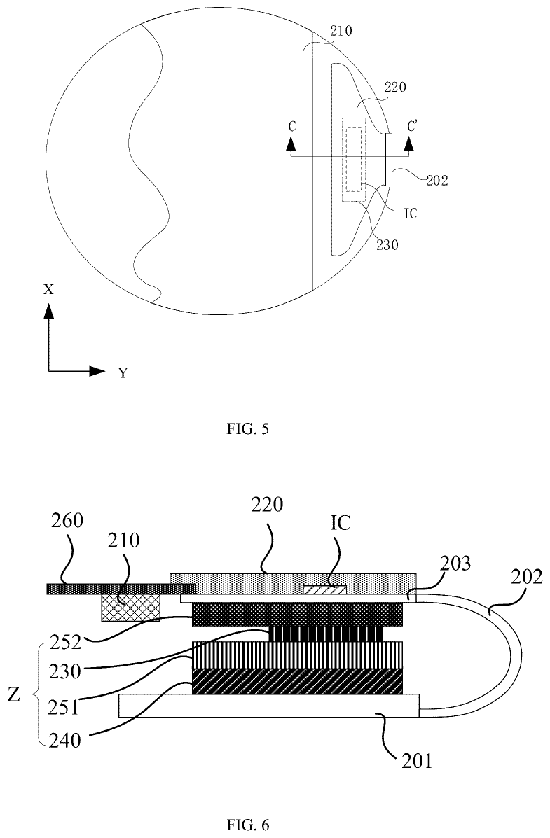

In view of this, in some specific embodiments, the display module further includes a second shielding layer. FIG. 5 schematically shows a plan view of a display driving chip, a first shielding layer, a second shielding layer and a near field communication antenna in the embodiments of the present disclosure, and FIG. 6 schematically shows a cross-sectional view along a section line CC′ of FIG. 5. Referring to FIG. 5 and FIG. 6, the second shielding layer 230 is located on a side of the display driving chip IC close to the display portion 201, and the orthographic projection of the display driving chip IC on the display portion 201 is located within an orthographic projection of the second shielding layer 230 on the display portion 201. In this way, the display driving chip IC may be covered and protected by the second shielding layer 230 to shield the static electricity from a side of the display driving chip IC close to the display portion 201, thereby improving the anti-static ability of the display driving chip IC.

Optionally, the second shielding layer 230 may be arranged opposite to the display driving chip IC and be slightly larger than the display driving chip IC, so that the area occupied by the second shielding layer 230 is as small as possible on the basis of being able to play the role of electrostatic protection.

In some specific embodiments, the display module further includes a support structure Z, which is located on a side of the display driving chip IC close to the display portion 201, and the support structure Z includes the above-mentioned second shielding layer 230, and the orthographic projection of the display driving chip IC on the display portion 201 is located within the orthographic projection of the second shielding layer 230 on the display portion 201.

In some specific embodiments, the support structure Z is located between the binding portion 203 and the display portion 201, and the support structure Z is used to support the binding portion 203 and the display portion 201. For example, referring to FIG. 6, the support structure Z further includes a spacer layer 240 and a first adhesive layer 251, the spacer layer 240 is located on a side of the second shielding layer 230 close to the display portion 201, and the first adhesive layer 251 is located between the spacer layer 240 and the second shielding layer 230.

In the embodiments of the present disclosure, the display module further includes a back film (not shown in the figure) provided on a side of the display portion 201 facing the binding portion 203, and the spacer layer 240 may be located on a side of the back film away from the display portion 201.

The material of the spacer layer 240 may include foam and graphite, so that the spacer layer 240 may not only play a supporting role, but also play a heat dissipation role through graphite.

In some specific embodiments, the support structure Z further includes a second adhesive layer 252, and the second adhesive layer 252 is located on a side of the second shielding layer 230 away from the display portion 201.

In some specific embodiments, a thickness of the second shielding layer 230 may be adjusted so that the second shielding layer 230 may play a role in heat dissipation. Optionally, the thickness of the second shielding layer 230 may be set between 0.2 μm and 0.6 μm. For example, the thickness of the second shielding layer 230 may be set at 0.5 μm.

In some specific embodiments, a thickness of the first shielding layer 220 may be set between 0.2 μm and 0.6 μm. For example, the thickness of the second shielding layer 230 may be set at 0.5 μm.

In some specific embodiments, the first shielding layer 220 is attached to the surface of the display driving chip IC. Optionally, the thickness of the first shielding layer 220 is different from the thickness of the second shielding layer 230. Optionally, the thickness of the first shielding layer 220 is less than the thickness of the second shielding layer 230. In this way, the first shielding layer 220 is thinner, which is conducive to being attached to the surface of the display driving chip IC, thereby forming a better electromagnetic shielding effect. Correspondingly, the second shielding layer 230 is thicker, which is conducive to achieving the above-mentioned heat dissipation effect. Besides, the larger thickness may also make the second shielding layer 230 play a supporting role. Compared with the spacer layer 240 composed of materials such as foam and graphite, the second shielding layer 230 composed of materials such as metal (specific details will be described in detail below) may play a better supporting effect.

It should be noted that in the embodiments of the present disclosure, the above thickness may refer to the average thickness or the maximum thickness.

In the embodiments of the present disclosure, the second shielding layer 230 may be formed on a side of the first adhesive layer 251 away from the display portion 201 by an electroplating process.

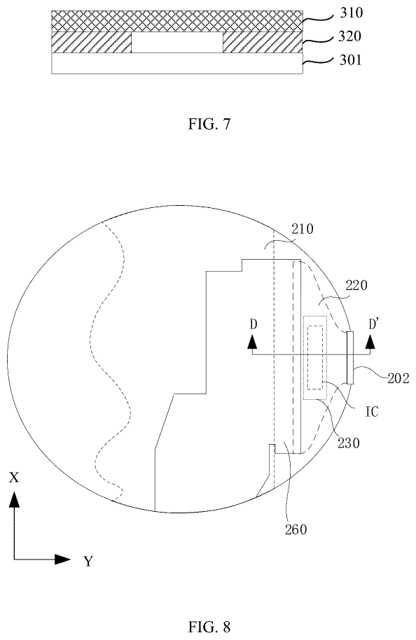

FIG. 7 schematically shows a schematic diagram of a display module in another comparative example. Referring to FIG. 7, in the comparative example, a fourth shielding layer 320 is provided between a near field communication antenna 310 and a display portion 301, and an orthographic projection of the fourth shielding layer 320 on the display portion 201 partially overlaps with an orthographic projection of the near field communication antenna 310 on the display portion 301. In this way, the effect of improving the anti-static ability is achieved by providing the fourth shielding layer 320 between the near field communication antenna 310 and the display portion 301. However, the inventors found in research that in the comparative example, since the orthographic projection of the fourth shielding layer 320 on the display portion 301 partially overlaps with the orthographic projection of the near field communication antenna 310 on the display portion 301, the fourth shielding layer 320 will interfere with the transmission and reception of electromagnetic signals by the near field communication antenna 310, thereby affecting the function of the near field communication antenna 310.

In view of this, in some specific embodiments of the present disclosure, the orthographic projection of the near field communication antenna 210 on the display portion 201 is spaced apart from the orthographic projection of the second shielding layer 230 on the display portion 201.

Exemplarily, the orthographic projection of the near field communication antenna 210 on the display portion 201 may at least partially surround the orthographic projection of the second shielding layer 230 on the display portion 201, or the orthographic projection of the near field communication antenna 210 on the display portion 201 and the orthographic projection of the second shielding layer 230 on the display portion 201 may be arranged along the first direction Y. For example, referring to FIG. 5, the orthographic projection of the near field communication antenna 210 on the display portion 201 is located on the left side of the orthographic projection of the second shielding layer 230 on the display portion 201.

In this way, the second shielding layer 230 may not only achieve the effect of improving the anti-static ability, but also the second shielding layer 230 will not interfere with the transmission and reception of electromagnetic signals by the near field communication antenna 210, thereby preventing the caused problem of affecting the function of the near field communication antenna 210.

Referring to FIG. 5, in some specific embodiments, the orthographic projection of the second shielding layer 230 on the display portion 201 is located within the orthographic projection of the first shielding layer 220 on the display portion 201.

Referring to FIG. 5 and FIG. 6, the display driving chip IC may be sandwiched between the first shielding layer 220 and the second shielding layer 230 to form a sandwich structure, thereby not only shielding the electromagnetic signal from a side of the display driving chip IC away from the display portion 201, but also shielding the electromagnetic signal from a side of the display driving chip IC close to the display portion 201, thereby improving the electromagnetic signal shielding effect.

Furthermore, by making the orthographic projection of the second shielding layer 230 on the display portion 201 within the orthographic projection of the first shielding layer 220 on the display portion 201, an area of the first shielding layer 220 may be larger than an area of the second shielding layer 230. In this way, the first shielding layer 220 may not only cover the display driving chip IC, but also cover the signal line electrically connected to the display driving chip IC, thereby preventing electromagnetic signals from interfering with the electrical signals on the signal line.

In some specific embodiments, the orthographic projection of the near field communication antenna 210 on the display portion 201 is spaced apart from the orthographic projection of the first shielding layer 220 on the display portion 201.

Exemplarily, the orthographic projection of the near field communication antenna 210 on the display portion 201 may at least partially surround the orthographic projection of the first shielding layer 220 on the display portion 201, or the orthographic projection of the near field communication antenna 210 on the display portion 201 and the orthographic projection of the first shielding layer 220 on the display portion 201 may be arranged along the first direction Y. For example, referring to FIG. 5, the orthographic projection of the near field communication antenna 210 on the display portion 201 is located on a left side of the orthographic projection of the first shielding layer 220 on the display portion 201.

In some specific embodiments, the display driving chip IC is located on a side of the binding portion 203 away from the display portion 201, and the second shielding layer 230 is located on a side of the binding portion 203 facing the display portion 201.

In the embodiments of the present disclosure, when preparing a display module, the second shielding layer 230 may be disposed on a back side of the display portion 201, and the display driving chip IC may be bound to a first surface of the binding portion 203. Next, the binding portion 203 is bent to a back side of the display portion 201, and the first surface is directed toward a side away from the display portion 201. Alternatively, when preparing a display module, the display driving chip IC may be bound to a first surface of the binding portion 203, and the second shielding layer 230 may be disposed on a second surface of the binding portion 203. The second surface may refer to a surface of the binding portion 203 that is disposed opposite to the first surface along the thickness direction of the binding portion 203. For example, referring to FIG. 6, the first surface may refer to the upper surface of the binding portion 203, and the second surface may refer to the lower surface of the binding portion 203.

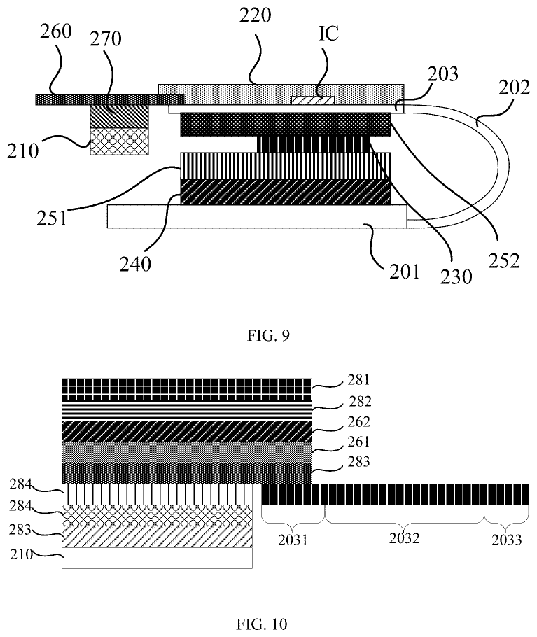

FIG. 8 schematically shows a first plan view of a display driving chip, a first shielding layer, a second shielding layer, a flexible circuit board and a near field communication antenna in the embodiments of the present disclosure, and FIG. 9 schematically shows a cross-sectional view of FIG. 8 along a section line DD'. Referring to FIGS. 8 and 9, in some specific embodiments, the display module further includes a flexible circuit board 260 and a third shielding layer 270. The flexible circuit board 260 is electrically connected to the binding portion 203 and the near field communication antenna 210, and the flexible circuit board 260 is located on a side of the near field communication antenna 210 away from the display portion 201. The third shielding layer 270 is located between the near field communication antenna 210 and the flexible circuit board 260.

In the embodiments of the present disclosure, the third shielding layer 270 may improve the problem of incomplete coverage of the first shielding layer 220 due to the limitation of the preparation process, thereby further improving the anti-electromagnetic interference capability of the display driving chip IC.

In some specific embodiments, a thickness of the third shielding layer 270 is different from a thickness of the first shielding layer 220 and a thickness of the second shielding layer 220. For example, the thickness of the third shielding layer 270 is greater than the thickness of the first shielding layer 220. Optionally, the thickness of the third shielding layer 270 is greater than the thickness of the second shielding layer 220. Optionally, the thickness of the third shielding layer 270 may be set between 0.4 μm and 0.7 μm, for example, the thickness of the second shielding layer 230 may be set at 0.6 μm. In this way, the flexible circuit board 260 may be routed on the third shielding layer 270, and a larger thickness is conducive to reducing resistance.

Optionally, when preparing a display module, integrated flexible circuit board 260 and near field communication antenna 210 may be prepared first, and then the integrated near field communication antenna 210 and flexible circuit board 260 may be arranged on a back side of the display portion 201.

Exemplarily, the integrated near field communication antenna 210 and the flexible circuit board 260 may specifically refer to the near field communication antenna 210 and the flexible circuit board 260 being bound and connected. For example, when preparing the integrated flexible circuit board 260 and near field communication antenna 210, the near field communication antenna 210 may be bonded to the main part of the flexible circuit board 260, and the near field communication antenna 210 may be connected to a signal terminal on the flexible circuit board 260 by binding.

In the process of preparing the integrated flexible circuit board 260 and near field communication antenna 210, the third shielding layer 270 is formed between the flexible circuit board 260 and the near field communication antenna 210. The pattern of the third shielding layer 270 may be designed according to the functional requirements of the near field communication antenna 210, and the embodiments of the present disclosure are not limited to this. For example, the pattern of the third shielding layer 270 may be matched with the driving signal of the near field communication antenna 210, so that the near field communication antenna 210 may achieve the expected effect of receiving and transmitting electromagnetic signals.

In some specific embodiments, an orthographic projection of the third shielding layer 270 on the display portion 201 is spaced apart from the orthographic projection of the first shielding layer 220 on the display portion 201.

As described above, after the third shielding layer 270 is provided, the driving signal of the near field communication antenna 210 needs to be matched with the pattern of the third shielding layer 270. After the orthographic projection of the third shielding layer 270 on the display portion 201 is spaced apart from the orthographic projection of the first shielding layer 220 on the display portion 201, the design of the driving signal of the near field communication antenna 210 does not need to consider the first shielding layer 220, thereby reducing the difficulty of matching.

In some specific embodiments, the first shielding layer 220 is located on a side of the flexible circuit board 260 away from the display portion 201, and the orthographic projection of a part of the flexible circuit board 260 electrically connected to the binding portion 203 on the display portion 201 is located within the orthographic projection of the first shielding layer 220 on the display portion 201.

In the embodiments of the present disclosure, the flexible circuit board 260 may be arranged with the display driving chip IC along the first direction Y. For example, referring to FIG. 8, the flexible circuit board 260 is located on the left side of the display driving chip IC. The side of the flexible circuit board 260 close to the display driving chip IC is electrically connected to the binding portion 203. For example, the right side of the flexible circuit board 260 is electrically connected to the binding portion 203. Then, the left end of the first shielding layer 220 may cover the part where the flexible circuit board 260 is electrically connected to the binding portion 203. In this way, the first shielding layer 220 may shield the electromagnetic signal of the part where the flexible circuit board 260 is electrically connected to the binding portion 203. At the same time, the first shielding layer 220 may also prevent the physical damage to the electrically connected part by external impact, thereby improving the product yield.

FIG. 10 schematically shows a cross-sectional view of a flexible circuit board 260, a near field communication antenna 210 and a binding portion 203 in the embodiments of the present disclosure. Referring to FIG. 10, in some specific embodiments, the flexible circuit board 260 includes a base layer 261 and a wiring layer 262, the wiring layer 262 is located on a side of the base layer 261 away from the display portion 201, and a side of the base layer 261 close to the display portion 201 is bound and connected to a side of the binding portion 203 away from the display portion 201.

In the embodiments of the present disclosure, a first buffer layer 281 may also be provided on a side of the wiring layer 262 away from the display portion 201, and the first buffer layer 281 and the wiring layer 262 are bonded by a first bonding layer 282. Optionally, a material of the first buffer layer 281 may include polyimide (PI).

In some specific embodiments, the binding portion 203 includes a first portion 2031, a second portion 2032, and a third portion 2033 arranged in sequence along the first direction Y, the first portion 2031 is bound and connected to the base layer 261, the second portion 2032 is bound and connected to the display driving chip IC, and the third portion 2033 is electrically connected to the bending portion 202. For example, referring to FIG. 10, the binding portion 203 includes a first portion 2031, a second portion 2032, and a third portion 2033 arranged in sequence from left to right.

In some specific embodiments, an electroplated metal layer 283 is provided on a side of the base layer 261 facing the display portion 201. Optionally, the third shielding layer 270 is located in the electroplated metal layer 283.

In some specific embodiments, the flexible circuit board 260 is bound and connected to the binding portion 203, which may specifically mean that a side of the electroplated metal layer 283 of the flexible circuit board 260 close to the display portion 201 is bound and connected to a side of the first potion 2031 of the binding portion 203 away from the display portion 201. For example, the lower end of the electroplated metal layer 283 of the flexible circuit board 260 is bound and connected to the upper end of the first portion 2031 of the binding portion 203.

In some specific embodiments, a second buffer layer 284 may be provided between the electroplated metal layer 283 and the near field communication antenna 210, the second buffer layer 284 and the near field communication antenna 210 are bonded by a second adhesive layer 285, and the second buffer layer 284 and the electroplated metal layer 283 are bonded by a third adhesive layer 286.

Optionally, a material of the second buffer layer 284 may include polyimide (PI).

Optionally, a material of the second bonding layer 285 and a material the third bonding layer 286 may be different.

Optionally, a material of the second bonding layer 285 and a material of the first bonding layer 282 may be the same.

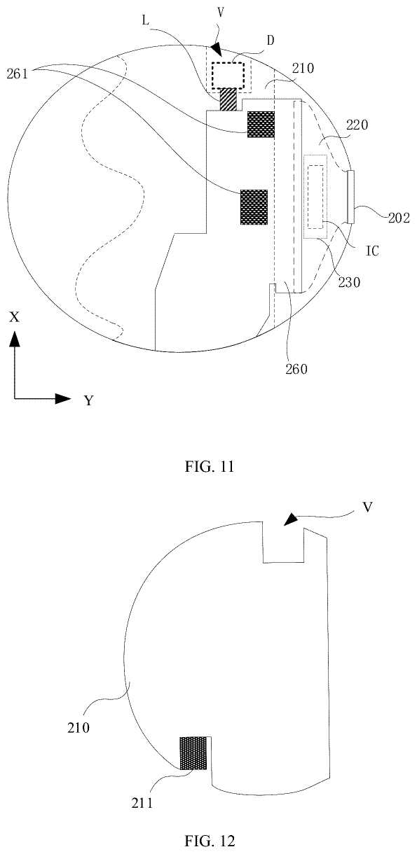

FIG. 11 schematically shows a second plan view of a display driving chip, a first shielding layer, a second shielding layer, a flexible circuit board and a near field communication antenna in the embodiments of the present disclosure. Referring to FIG. 11, in some specific embodiments, at least one opening V is provided on the near field communication antenna 210, and the at least one opening V is used to provide a photosensitive element D. An orthographic projection of the opening V on the display portion 201 and the orthographic projection of the flexible circuit board 260 on the display portion 201 are arranged along the second direction X, and the second direction X intersects with the first direction Y.

In the embodiments of the present disclosure, the photosensitive element D may include an element for detecting physiological characteristic signals, for example, the photosensitive element D may include a heartbeat detection element, etc. The photosensitive element D may adopt any form of photosensitive method, for example, the photosensitive element D may adopt an infrared photosensitive method, etc.

In some specific embodiments, the photosensitive element D may be electrically connected to the flexible circuit board 260 through a signal line L located on a side of the near field communication antenna 210 away from the display portion 201.

FIG. 12 schematically shows a plan view of a near field communication antenna in the embodiments of the present disclosure. Referring to FIG. 12, in some specific embodiments, the near field communication antenna 210 includes a signal binding terminal 211, and the signal binding terminal 211 is bound and connected to the flexible circuit board 260. Optionally, in the second direction X, an orthographic projection of the signal binding terminal 211 on the display portion 201 is located on a side where the orthographic projection of the opening V for arranging the photosensitive element D on the near field communication antenna 210 on the display portion 201 is close to the orthographic projection of the display driving chip IC on the display portion 201.

For example, referring to FIG. 11 and FIG. 12, the opening V for arranging the photosensitive element D on the near field communication antenna 210 is located at the upper end, and the signal binding terminal 211 of the near field communication antenna 210 is located at the lower end.

In some specific embodiments, at least one signal test terminal 261 is provided on the flexible circuit board 260, and an orthographic projection of the signal test terminal 261 on the display portion 201 is spaced apart from the orthographic projection of the first shielding layer 220 on the display portion 201.

In the embodiments of the present disclosure, two signal test terminals 261 are provided on the flexible circuit board 260, and the product test may be performed through the signal test terminals 261 before the product is assembled.

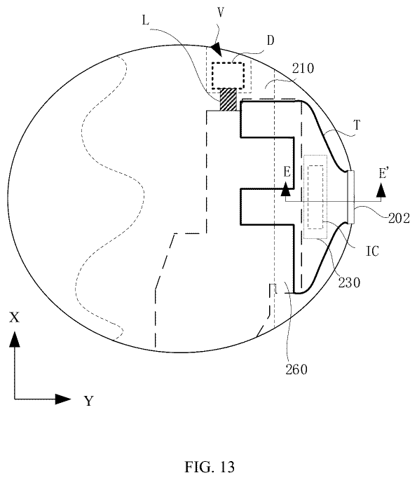

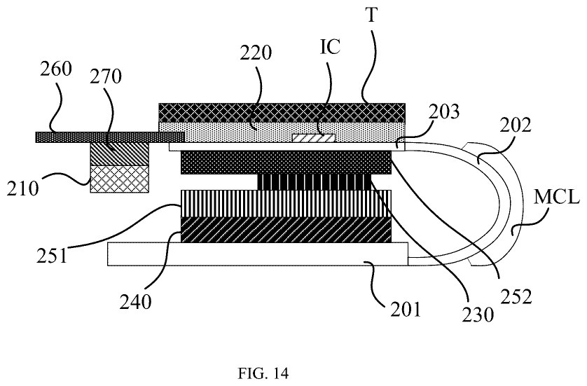

FIG. 13 schematically shows a plan view of a display driving chip, a covering tape, a first shielding layer, a second shielding layer, a flexible circuit board and a near field communication antenna in the embodiments of the present disclosure, and FIG. 14 schematically shows a cross-sectional view of FIG. 13 along a section line EE′. Referring to FIGS. 13 and 14, in some specific embodiments, the display module further includes a covering tape T. After the test is completed, the signal test terminal 261 may be covered by the covering tape T.

In some specific embodiments, the covering tape T is located on a side of the first shielding layer 220 away from the display portion 201, and the orthographic projection of the first shielding layer 220 on the display portion 201 is located within an orthographic projection of the covering tape T on the display portion 201.

In the embodiments of the present disclosure, the electromagnetic shielding metal may be formed on the covering tape T by electroplating process, and then the covering tape T formed with electromagnetic shielding metal is covered on the display driving chip IC to obtain the first shielding layer 220.

When preparing the covering tape T formed with electromagnetic shielding metal, a part of the covering tape T used to cover the signal test terminal 261 may not form electromagnetic shielding metal. In this way, after the covering tape T formed with electromagnetic shielding metal is covered on the display driving chip IC, the orthographic projection of the signal test terminal 261 on the display portion 201 is spaced apart from the orthographic projection of the first shielding layer 220 on the display portion 201, thereby minimizing the area occupied by the first shielding layer 220.

Referring to FIGS. 11 and 13, in some specific embodiments, a plurality of signal test terminals 261 are provided on the flexible circuit board 260, and the plurality of signal test terminals 261 are arranged along the second direction X. For example, two signal test terminals 261 are provided on the flexible circuit board 260, and the two signal test terminals 261 may be used to test different signals, or at least part of the two signal test terminals 261 may be used to test the same signal, thereby playing the role of signal terminal multiplexing or signal terminal standby.

In some specific embodiments, the display module further includes a second shielding layer 230, the second shielding layer 230 is located on a side of the display driving chip IC close to the display portion 201, and the orthographic projection of the display driving chip IC on the display portion 201 is located within the orthographic projection of the second shielding layer 230 on the display portion 201. The orthographic projection of the flexible circuit board 260 on the display portion 201 is spaced apart from the orthographic projection of the second shielding layer 230 on the display portion 201.

Optionally, the orthographic projection of the flexible circuit board 260 on the display portion 201 and the orthographic projection of the second shielding layer 230 on the display portion 201 are arranged along the first direction Y. For example, referring to FIG. 11, the orthographic projection of the flexible circuit board 260 on the display portion 201 is located on a left side of the orthographic projection of the second shielding layer 230 on the display portion 201. It should be noted that in the embodiments of the present disclosure, the incomplete description of the second shielding layer 230 may be referred to the aforementioned embodiments, so it will not be repeated here.

In some specific embodiments, the orthographic projection of the binding portion 203 on the display portion 201 is located within the orthographic projection of the first shielding layer 220 on the display portion 201, so that the first shielding layer 220 may play an electromagnetic shielding role for the signal line on the entire binding portion 203.

In some specific embodiments, a material of the first shielding layer 220 includes a ductile metal material. For example, the material of the first shielding layer 220 includes copper foil.

In the embodiments of the present disclosure, the ductile metal material has stronger plasticity, which is conducive to achieving better attachment of the first shielding layer 220 to the display driving chip IC. At the same time, the display substrate in the embodiments of the present disclosure may be a flexible display substrate. Compared with rigid materials, the ductile metal material is more conducive to meeting the flexibility of the flexible display substrate, such as bendability.

In some specific embodiments, the material of the first shielding layer 220 may be an alloy material in addition to a single metal material. For example, the material of the first shielding layer 220 may include an alloy material composed of at least two of gold, silver, copper and nickel.

In some specific embodiments, the material of the first shielding layer 220 may also include other materials with conductive or magnetic properties. For example, the material of the first shielding layer 220 may also include graphite and conductive cloth. The conductive cloth may refer to metal fibers formed by covering metal materials on the surface of fiber fabrics. The metal materials may include, for example, gold, silver, copper, and nickel.

In some specific embodiments, a metal covering layer MCL is provided on a side of the bending portion 202 away from the second shielding layer 230. The metal covering layer MCL is conducive to releasing the stress on the bending portion 202.

Optionally, an orthographic projection of the first shielding layer 220 in the thickness direction of the display module is spaced from an orthographic projection of the metal covering layer MCL in the thickness direction of the display module. For example, the spacing between the orthographic projection of the first shielding layer 220 in the thickness direction of the display module and the orthographic projection of the metal covering layer MCL in the thickness direction of the display module is set between 0.5 cm and 2.5 cm. Optionally, the materials of the first shielding layer 220, the second shielding layer 230 and the third shielding layer 270 are the same, for example, the materials of the three all include copper foil.

Optionally, the first shielding layer 220, the second shielding layer 230 and the third shielding layer 270 may all be formed by an electroplating process.

At least some embodiments of the present disclosure also provide a display device, the display panel includes the display module as described above. The display device may include any device or product having a display function. For example, the display device may be a smart phone, a mobile phone, an e-book reader, a desktop computer (PC), a laptop PC, a netbook PC, a personal digital assistant (PDA), a portable multimedia player (PMP), a digital audio player, a mobile medical device, a camera, a wearable device (such as a head-mounted device, an electronic clothing, an electronic bracelet, an electronic necklace, an electronic accessory, an electronic tattoo, or a smart watch), a television, etc.

In the embodiments of the present disclosure, the display device may specifically be a smart watch with an NFC function. Since the near field communication antenna 210 for implementing the NFC function is spaced apart from the display driving chip IC for providing the display driver signal, and the first shielding layer 220 is provided for the display driving chip IC, electromagnetic signals may be prevented from interfering with the display driving chip IC when the smart watch is charging, thereby improving the water ripple problem caused thereby.

It should be noted that the details not described in detail in the embodiments of the present disclosure may be specifically referred to the aforementioned embodiments, which will not be repeated here.

Although some embodiments of the overall technical concept of the present disclosure have been shown and described, ordinary technicians in the field will understand that changes mnay be made to these embodiments without departing from the principles and spirit of the overall technical concept, and the scope of the present disclosure is defined by the claims and their equivalents.

1. A display module, comprising:
a display substrate, wherein the display substrate comprises a display portion, a bending portion and a binding portion, and the binding portion is bent to a back side of the display portion through the bending portion;
a display driving chip, wherein the display driving chip is bound to the binding portion;
a near field communication antenna, wherein the near field communication antenna is located on the back side of the display portion, and an orthographic projection of the near field communication antenna on the display portion is spaced apart from an orthographic projection of the display driving chip on the display portion; and
a first shielding layer, wherein the first shielding layer is located on a side of the display driving chip away from the display portion, and the orthographic projection of the display driving chip on the display portion is located within an orthographic projection of the first shielding layer on the display portion.

2. The display module according to claim 1, wherein the display module further comprises a second shielding layer, the second shielding layer is located on a side of the display driving chip close to the display portion, and the orthographic projection of the display driving chip on the display portion is located within an orthographic projection of the second shielding layer on the display portion.

3. The display module according to claim 2, wherein the orthographic projection of the near field communication antenna on the display portion is spaced apart from the orthographic projection of the second shielding layer on the display portion.

4. The display module according to claim 2, wherein the orthographic projection of the second shielding layer on the display portion is located within the orthographic projection of the first shielding layer on the display portion.

5. The display module according to claim 2, wherein the orthographic projection of the near field communication antenna on the display portion is spaced apart from the orthographic projection of the first shielding layer on the display portion.

6. The display module according to claim 2, wherein the display driving chip is located on a side of the binding portion away from the display portion, and the second shielding layer is located on a side of the binding portion facing the display portion.

7. The display module according to claim 1, wherein the display module further comprises:
a flexible circuit board electrically connected to the binding portion and the near field communication antenna, and the flexible circuit board is located on a side of the near field communication antenna away from the display portion; and
a third shielding layer located between the near field communication antenna and the flexible circuit board.

8. The display module according to claim 7, wherein an orthographic projection of the third shielding layer on the display portion is spaced apart from the orthographic projection of the first shielding layer on the display portion.

9. The display module according to claim 7, wherein the first shielding layer is located on a side of the flexible circuit board away from the display portion, and an orthographic projection of a part of the flexible circuit board electrically connected to the binding portion on the display portion is located within the orthographic projection of the first shielding layer on the display portion.

10. The display module according to claim 7, wherein the flexible circuit board comprises a base layer and a wiring layer, the wiring layer is located on a side of the base layer away from the display portion, and a side of the base layer close to the display portion is bound and connected to a side of the binding portion away from the display portion.

11. The display module according to claim 10, wherein the binding portion comprises a first portion, a second portion and a third portion arranged in sequence along a first direction, the first portion is bound and connected to the base layer, the second portion is bound and connected to the display driving chip, and the third portion is electrically connected to the bending portion.

12. The display module according to claim 11, wherein at least one opening is provided on the near field communication antenna, the at least one opening is configured to provide a photosensitive element, an orthographic projection of the opening on the display portion and an orthographic projection of the flexible circuit board on the display portion are arranged along a second direction, and the second direction intersects with the first direction.

13. The display module according to claim 7, wherein at least one signal test terminal is provided on the flexible circuit board, and an orthographic projection of the signal test terminal on the display portion is spaced apart from the orthographic projection of the first shielding layer on the display portion.

14. The display module according to claim 7, wherein the display module further comprises a second shielding layer, the second shielding layer is located on a side of the display driving chip close to the display portion, the orthographic projection of the display driving chip on the display portion is located within an orthographic projection of the second shielding layer on the display portion; and
an orthographic projection of the flexible circuit board on the display portion is spaced apart from the orthographic projection of the second shielding layer on the display portion.

15. The display module according to claim 7, wherein the near field communication antenna is bound and connected to the flexible circuit board.

16. The display module according to claim 1, wherein the display module further comprises a covering tape, the covering tape is located on a side of the first shielding layer away from the display portion, and the orthographic projection of the first shielding layer on the display portion is located within an orthographic projection of the covering tape on the display portion.

17. The display module according to claim 1, wherein an orthographic projection of the binding portion on the display portion is located within the orthographic projection of the first shielding layer on the display portion,
wherein a material of the first shielding layer comprises a ductile metal material.

18. (canceled)

19. A display module, comprising:
a display substrate, wherein the display substrate comprises a display portion, a bending portion and a binding portion, and the binding portion is bent to a back side of the display portion through the bending portion;
a display driving chip, wherein the display driving chip is bound to the binding portion;
a near field communication antenna, wherein the near field communication antenna is located on the back side of the display portion, and an orthographic projection of the near field communication antenna on the display portion is spaced apart from an orthographic projection of the display driving chip on the display portion;
a first shielding layer, wherein the first shielding layer is located on a side of the display driving chip away from the display portion, and the orthographic projection of the display driving chip on the display portion is located within an orthographic projection of the first shielding layer on the display portion; and
a support structure located on a side of the display driving chip close to the display portion, wherein the support structure comprises a second shielding layer, and an orthographic projection of the display driving chip on the display portion is located within an orthographic projection of the second shielding layer on the display portion.

20-30. (canceled)

31. A display device, comprising the display module of claim 1.

32. A display device, comprising the display module of claim 19.
